(19) United States
(12) Patent Application Publication
(10) Pub. No.: US 2024/0134277 A1
(43) Pub. Date: Apr. 25, 2024

(54) PHOTOSENSITIVE RESIN COMPOSITION, PHOTOSENSITIVE ELEMENT, PRINTED WIRING BOARD, AND METHOD FOR MANUFACTURING PRINTED WIRING BOARD

(71) Applicant: Resonac Corporation, Tokyo (JP)

(72) Inventors: Yuta DAIJIMA, Tokyo (JP); Shuji NOMOTO, Tokyo (JP); Akihiro NAKAMURA, Tokyo (JP); Naomitsu KOMORI, Tokyo (JP)

(21) Appl. No.: 18/262,276

(22) PCT Filed: Dec. 21, 2022
(86) PCT No.: PCT/JP2022/047086

§ 371 Date: Jul. 20, 2023

(30) Foreign Application Priority Data
Dec. 22, 2021 (JP) 2021-208259

(51) Int. Cl. G03F 7/033; G03F 7/028; H05K 3/06; H05K 3/12

(52) U.S. Cl. CPC G03F 7/033; G03F 7/028; H05K 3/064; H05K 3/1283; H05K 2203/0582

(57) ABSTRACT

A photosensitive resin composition according to the present disclosure, contains an acid-modified vinyl group-containing resin (A), a thermosetting resin (B), a photopolymerization initiator (C), and a photopolymerizable compound (D), in which the photopolymerizable compound includes a photopolymerizable compound having a polyoxyalkylene chain and an ethylenically unsaturated group.

### TECHNICAL FIELD

The present disclosure relates to a photosensitive resin composition, a photosensitive element, a printed wiring board, and a method for manufacturing a printed wiring board.

### BACKGROUND ART

In the field of a printed wiring board, a permanent resist is formed on the printed wiring board. When using the printed wiring board, the permanent resist has a function of preventing the corrosion of a conductor layer or retaining electrical insulating properties between the conductor layers. Recently, even in a step of performing flip chip mounting, wire bonding mounting, or the like of a semiconductor element on the printed wiring board through solder, the permanent resist prevents the solder from being attached to an unnecessary portion of the conductor layer of the printed wiring board and also functions as a solder resist film. In the related art, the permanent resist is produced by a screen printing method using a thermosetting resin composition or a photography using a photosensitive resin composition. For example, in a flexible wiring board using a mounting method such as flip chip (FC), tape automated bonding (TAB), and chip on film (COF), a thermosetting resin paste is screen-printed excluding a connection wiring pattern portion with an IC chip, an electronic component, or a liquid crystal display (LCD) panel, and is thermal-cured to form the permanent resist (for example, refer to Patent Literature 1).

In a semiconductor package substrate such as a ball grid array (BGA) and a chip size package (CSP) mounted on the electronic component, (1) in order to flip-chip-mount the semiconductor element on the semiconductor package substrate through the solder, (2) in order to wire-bonding-join the semiconductor element and the semiconductor package substrate, and (3) in order to solder-join the semiconductor package substrate onto a motherboard substrate, it is necessary to remove the permanent resist at the joint. In the image formation of the permanent resist, a photography is used in which the photosensitive resin composition is applied and dried, and then, is selectively irradiated with an active light ray such as an ultraviolet ray, and is cured, and only the unirradiated portion is developed and removed to form an image. The photography is excellent in workability, and is suitable for mass production, thereby being widely used in the image formation of a photosensitive material in the industry of an electronic material (for example, refer to Patent Literature 2).

### CITATION LIST

### Patent Literature

Patent Literature 1: JP 2003-198105 A
Patent Literature 2: JP 2011-133851 A

### SUMMARY OF INVENTION

### Technical Problem

The permanent resist (a solder resist) is also required to have higher performance, in response to an increase in the density of the printed wiring board. In particular, a demand for the formation of a fine pattern and thermal shock resistance has increased annually, and it has been important to make such properties highly compatible. However, in the permanent resist containing the photosensitive resin composition of the related art, when forming a fine pattern, resolution may not be sufficient, hemming may occur in the opening, which causes the closure of the opening, a photosensitive layer around the opening may be excessively developed into an undercut shape, and a crack may occur in the formed permanent resist.

An object of the present disclosure is to provide a photosensitive resin composition having excellent resolution and pattern forming properties and capable of forming a permanent resist excellent in thermal shock resistance, and a photosensitive element, a printed wiring board, and a method for manufacturing a printed wiring board, using the photosensitive resin composition described above.

### Solution to Problem

One aspect of the present disclosure relates to a photosensitive resin composition, comprising an acid-modified vinyl group-containing resin (A), a thermosetting resin (B), a photopolymerization initiator (C), and a photopolymerizable compound (D), in which the photopolymerizable compound (D) includes a photopolymerizable compound having a polyoxyalkylene chain and an ethylenically unsaturated group.

Another aspect of the present disclosure relates to a photosensitive element, comprising a support film and a photosensitive layer formed on the support film, in which the photosensitive layer contains the photosensitive resin composition described above.

Another aspect of the present disclosure relates to a printed wiring board, comprising a permanent resist containing a cured material of the photosensitive resin composition described above.

Another aspect of the present disclosure relates to a method for manufacturing a printed wiring board, comprising a step of forming a photosensitive layer on a substrate by using the photosensitive resin composition or the photosensitive element described above; a step of forming a resist pattern by exposing and developing the photosensitive layer; and a step of forming a permanent resist by curing the resist pattern.

### Advantageous Effects of Invention

According to the present disclosure, it is possible to provide the photosensitive resin composition having excellent resolution and pattern forming properties and capable of forming the permanent resist excellent in the thermal shock resistance, and the photosensitive element, the printed wiring board, and the method for manufacturing a printed wiring board, using the photosensitive resin composition described above.

### BRIEF DESCRIPTION OF DRAWINGS

FIG. 1 is a sectional view schematically illustrating a photosensitive element according to this embodiment.

### DESCRIPTION OF EMBODIMENTS

The contents of a photosensitive resin composition according to an embodiment of the present disclosure, and a photosensitive element, a printed wiring board, and a method for manufacturing a printed wiring board, using the photosensitive resin composition described above will be listed as follows.
[1] A photosensitive resin composition, comprising an acid-modified vinyl group-containing resin (A), a thermosetting resin (B), a photopolymerization initiator (C), and a photopolymerizable compound (D), in which the photopolymerizable compound includes a photopolymerizable compound having a polyoxyalkylene chain and an ethylenically unsaturated group.
[2] The photosensitive resin composition according to [1] described above, in which the number of oxyalkylene groups in the polyoxyalkylene chain is 2 to 50.
[3] The photosensitive resin composition according to [1] described above, in which the number of oxyalkylene groups in the polyoxyalkylene chain is 10 to 35.
[4] The photosensitive resin composition according to any one of [1] to [3] described above, in which the photopolymerizable compound having a polyoxyalkylene chain and an ethylenically unsaturated group includes at least one type selected from the group consisting of an alkylene oxide-modified (meth)acrylate compound, an alkylene oxide-modified bisphenol A-type (meth)acrylate compound, an alkylene oxide-modified bisphenol F-type (meth)acrylate compound, an alkylene oxide-modified ditrimethylol propane (meth)acrylate compound, an alkylene oxide-modified dipentaerythritol (meth)acrylate compound, an alkylene oxide-modified pentaerythritol (meth)acrylate compound, an alkylene oxide-modified trimethylol propane (meth)acrylate compound, an alkylene oxide-modified diglycerin (meth)acrylate compound, and an alkylene oxide-modified glycerin (meth)acrylate compound.
[5] The photosensitive resin composition according to any one of [1] to [4] described above, in which the polyoxyalkylene chain includes at least one type selected from the group consisting of a polyoxyethylene chain, a polyoxypropylene chain, and a polyoxybutylene chain.
[6] The photosensitive resin composition according to any one of [1] to [5] described above, in which a content of the photopolymerizable compound is 1 to 15% by mass, on the basis of a total solid content in the photosensitive resin composition.
[7] The photosensitive resin composition according to any one of [1] to [6] described above, further comprising an inorganic filler (E).
[8] The photosensitive resin composition according to any one of [1] to [7] described above, further comprising an ion scavenger (G).
[9] The photosensitive resin composition according to any one of [1] to [8] described above, further comprising an elastomer (H).
[10] A photosensitive element, comprising a support film and a photosensitive layer formed on the support film, in which the photosensitive layer contains the photosensitive resin composition according to any one of [1] to [9] described above.
[11] A printed wiring board, including a permanent resist comprising a cured material of the photosensitive resin composition according to any one of [1] to [9] described above.
[12] A method for manufacturing a printed wiring board, comprising a step of forming a photosensitive layer on a substrate by using the photosensitive resin composition according to any one of [1] to [9] described above or the photosensitive element according to described above; a step of forming a resist pattern by exposing and developing the photosensitive layer; and a step of forming a permanent resist by curing the resist pattern.

Hereinafter, the present disclosure will be described in detail. In this specification, the term “step” includes not only an independent step but also a step that is not explicitly distinguishable from other steps insofar as a desired function of the step is attained. The term “layer” includes not only a structure in which a layer is formed on the entire surface but also a structure in which a layer is formed on a part of the surface when observed as a plan view. A numerical range represented by using “to” indicates a range including numerical values described before and after “to” as the minimum value and the maximum value, respectively. In numerical ranges described in stages in this specification, the upper limit value or the lower limit value of a numerical range in a certain stage may be replaced with the upper limit value or the lower limit value of a numerical range in the other stage. In the numerical range described in this specification, the upper limit value or the lower limit value of the numerical range may be replaced with values described in Examples.

In a case where the amount of each component in a composition is stated in this specification, and there are a plurality of substances corresponding to each component in the composition, unless otherwise specified, the amount of each component in the composition indicates the total amount of the plurality of substances in the composition.

In this specification, “(meth)acrylate” indicates at least one of “acrylate” and “methacrylate” corresponding thereto, and the same applies to other similar expressions such as a (meth)acrylic acid and (meth)acryloyl. In this specification, a “solid content” indicates a non-volatile content excluding volatile substances (water, a solvent, or the like) contained in a photosensitive resin composition, and also includes a component in the form of a liquid, starch syrup, and wax at a room temperature (approximately 25° C.).

[Photosensitive Resin Composition]

A photosensitive resin composition according to this embodiment contains an acid-modified vinyl group-containing resin (A), a thermosetting resin (B), a photopolymerization initiator (C), and a photopolymerizable compound (D), in which the photopolymerizable compound includes a photopolymerizable compound having a polyoxyalkylene chain and an ethylenically unsaturated group. The photosensitive resin composition according to this embodiment is a negative photosensitive resin composition, and a cured film of the photosensitive resin composition can be preferably used as a permanent resist. Hereinafter, each component used in the photosensitive resin composition of this embodiment will be described in more detail.

(Component (A): Acid-Modified Vinyl Group-Containing Resin)

The photosensitive resin composition according to this embodiment contains an acid-modified vinyl group-containing resin as a component (A). The acid-modified vinyl group-containing resin is not particularly limited insofar as the acid-modified vinyl group-containing resin has a vinyl bond, which is a photopolymerizable ethylenically unsaturated bond, and an alkali-soluble acid group.

Examples of a group having the ethylenically unsaturated bond of the component (A) include a vinyl group, an allyl group, a propargyl group, a butenyl group, an ethynyl group, a phenyl ethynyl group, a maleimide group, a nadi-imide group, and a (meth)acryloyl group. Among them, the (meth)acryloyl group is preferable from the viewpoint of reactivity and resolution. Examples of the acid group of the component (A) include a carboxy group, a sulfo group, and a phenolic hydroxyl group. Among them, the carboxy group is preferable from the viewpoint of the resolution.

It is preferable that the component (A) is an acid-modified vinyl group-containing epoxy derivative obtained by allowing a saturated group- or unsaturated group-containing polybasic acid anhydride (c) (hereinafter, may be referred to as a “component (c)”) to react with an a resin (A′) obtained by allowing an epoxy resin (a) (hereinafter, may be referred to as a “component (a)”) and an ethylenically unsaturated group-containing organic acid (b) (hereinafter, may be referred to as a “component (b)”) to react with each other.

Examples of the acid-modified vinyl group-containing epoxy derivative include acid-modified epoxy (meth)acrylate. The acid-modified epoxy (meth)acrylate is a resin obtained by acid-modifying epoxy (meth)acrylate, which is a reactant between the component (a) and the component (b), with the component (c). For example, as the acid-modified epoxy (meth)acrylate, an addition reactant obtained by adding a saturated or unsaturated polybasic acid anhydride to an esterified material obtained by allowing an epoxy resin and a vinyl group-containing monocarboxylic to react with each other can be used.

Examples of the component (A) include an acid-modified vinyl group-containing resin (A1) (hereinafter, may be referred to as a “component (A1)”) obtained by using a bisphenol novolac-type epoxy resin (a1) (hereinafter, may be referred to as an “epoxy resin (a1)”) as the component (a), and an acid-modified vinyl group-containing resin (A2) (hereinafter, may be referred to as a “component (A2)”) obtained by using an epoxy resin (a2) other than the epoxy resin (a1) (hereinafter, may be referred to as an “epoxy resin (a2)”) as the component (a).

Examples of the epoxy resin (a1) include an epoxy resin having a structural unit represented by Formula (I) or (II) described below.

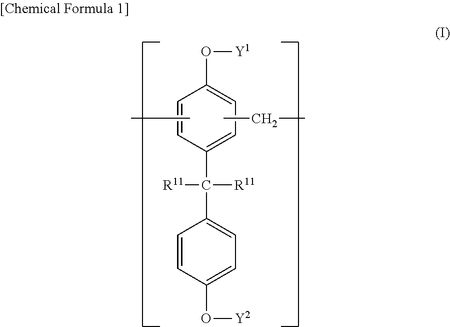

In Formula (I), RH indicates a hydrogen atom or a methyl group, and a plurality of R H may be the same or different from each other. Y¹ and Y² each independently indicate a hydrogen atom or a glycidyl group, and at least one of Y¹ and Y² is a glycidyl group. From the viewpoint of suppressing the occurrence of undercut and improving the linearity of a resist pattern outline and the resolution, it is preferable that R H is a hydrogen atom, and from the viewpoint of further improving thermal shock resistance, it is preferable that Y¹ and Y² are a glycidyl group.

The number of structural units represented by Formula (I) in the epoxy resin (a1) is 1 or more, and may be 10 to 100, 15 to 80, or 15 to 70. In a case where the number of structural units is in the range described above, the linearity of the resist pattern outline, adhesiveness to a copper substrate, heat resistance, and electrical insulating properties are easily improved. Here, the number of structural units indicates an integer value in a single molecule, and indicates a rational number, which is an average value, in an aggregate of a plurality of types of molecules. Hereinafter, the same applies to the number of structural units.

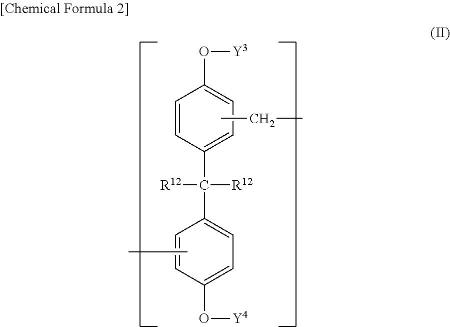

In Formula (II), R¹² indicates a hydrogen atom or a methyl group, and a plurality of R¹² may be the same or different from each other. Y³ and Y⁴ each independently indicate a hydrogen atom or a glycidyl group, and at least one of Y³ and Y⁴ is a glycidyl group. From the viewpoint of suppressing the occurrence of the undercut and improving the linearity of the resist pattern outline and the resolution, it is preferable that R¹² is a hydrogen atom, and from the viewpoint of further improving the thermal shock resistance, it is preferable that Y³ and Y⁴ are a glycidyl group.

The number of structural units represented by Formula (II) in the epoxy resin (a1) is 1 or more, and may be 10 to 100, 15 to 80, or 15 to 70. In a case where the number of structural units is in the range described above, the linearity of the resist pattern outline, the adhesiveness to the copper substrate, and the heat resistance are easily improved.

An epoxy resin in which in Formula (II), R¹² is a hydrogen atom, and Y³ and Y⁴ are a glycidyl group is commercially available as EXA-7376 series (Product Name, manufactured by DIC Corporation), and an epoxy resin in which in Formula (II), R¹² is a methyl group, and Y³ and Y⁴ are a glycidyl group is commercially available as EPON SU8 series (Product Name, manufactured by Mitsubishi Chemical Corporation).

The epoxy resin (a2) is not particularly limited insofar as the epoxy resin is different from the epoxy resin (a1), and is preferably at least one type selected from the group consisting of a novolac-type epoxy resin, a bisphenol A-type epoxy resin, a bisphenol F-type epoxy resin, a triphenol methane-type epoxy resin, and a biphenyl-type epoxy resin, from the viewpoint of suppressing the occurrence of the undercut and improving the linearity of the resist pattern outline, the adhesiveness to the copper substrate, and the resolution.

Examples of the novolac-type epoxy resin include an epoxy resin having a structural unit represented by Formula (III) described below. Examples of the bisphenol A-type epoxy resin or the bisphenol F-type epoxy resin include an epoxy resin having a structural unit represented by Formula (IV) described below. Examples of the triphenol methane-type epoxy resin include an epoxy resin having a structural unit represented by Formula (V) described below. Examples of the biphenyl-type epoxy resin include an epoxy resin having a structural unit represented by Formula (VI) described below.

As the epoxy resin (a2), a novolac-type epoxy resin having a structural unit represented by Formula (III) described below is preferable. Examples of the novolac-type epoxy resin having such a structural unit include a novolac-type epoxy resin represented by Formula (III′) described below.

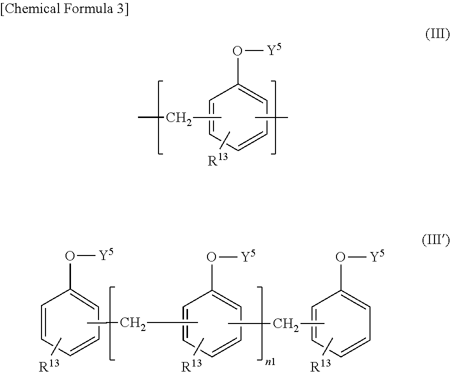

In Formulae (III) and (III′), R¹³ indicates a hydrogen atom or a methyl group, Y⁵ indicates a hydrogen atom or a glycidyl group, and at least one of Y⁵ is a glycidyl group. In Formula (III′), n₁ is a number of 1 or more, a plurality of R¹³ and Y⁵ may be the same or different from each other, respectively. From the viewpoint of suppressing the occurrence of the undercut and improving the linearity of the resist pattern outline and the resolution, it is preferable that R¹³ is a hydrogen atom.

In Formula (III′), a molar ratio of Y⁵, which is a hydrogen atom, to Y⁵, which is a glycidyl group, may be 0/100 to 30/70, or 0/100 to 10/90, from the viewpoint of suppressing the occurrence of the undercut and improving the linearity of the resist pattern outline and the resolution. n₁ is 1 or more, and may be 10 to 200, 30 to 150, or 30 to 100. In a case where n₁ is in the range described above, the linearity of the resist pattern outline, the adhesiveness to the copper substrate, and the heat resistance are easily improved.

Examples of the novolac-type epoxy resin represented by Formula (III′) include a phenol novolac-type epoxy resin and a cresol novolac-type epoxy resin. Such a novolac-type epoxy resin, for example, can be obtained by allowing a phenol novolac resin or a cresol novolac resin and epichlorohydrin to react with each other using a known method.

As the phenol novolac-type epoxy resin or the cresol novolac-type epoxy resin represented by Formula (III′), for example, YDCN-701, YDCN-702, YDCN-703, YDCN-704, YDCN-704L, YDPN-638, and YDPN-602 (Product Names, all are manufactured by NIPPON STEEL Chemical & Material Co., Ltd.), DEN-431 and DEN-439 (Product Names, all are manufactured by The Dow Chemical Company), EOCN-120, EOCN-1025, EOCN-1035, EOCN-1045, EOCN-1012, EOCN-1025, EOCN-1027, and BREN (Product Names, all are manufactured by Nippon Kayaku Co., Ltd.), EPN-1138, EPN-1235, and EPN-1299 (Product Names, all are manufactured by BASF), N-730, N-770, N-865, N-665, N-673, VH-4150, and VH-4240 (Product Names, all are manufactured by DIC Corporation), and the like are commercially available.

Examples of the epoxy resin (a2) preferably include a bisphenol A-type epoxy resin or a bisphenol F-type epoxy resin having a structural unit represented by Formula (IV) described below. Examples of the epoxy resin having such a structural unit include a bisphenol A-type epoxy resin or a bisphenol F-type epoxy resin represented by Formula (IV′) described below.

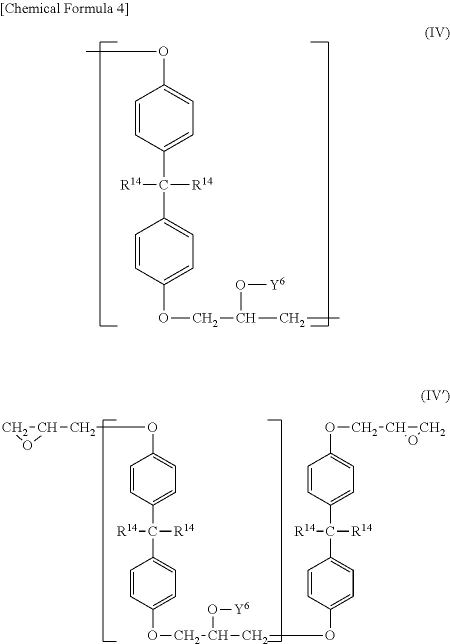

In Formulae (IV) and (IV′), R¹⁴ indicates a hydrogen atom or a methyl group, a plurality of R¹⁴ may be the same or different from each other, and Y⁶ indicates a hydrogen atom or a glycidyl group. In a case where in Formula (IV′), n₂ indicates a number of 1 or more, and n₂ is 2 or more, a plurality of Y⁶ may be the same or different from each other, and at least one of Y⁶ is a glycidyl group.

From the viewpoint of suppressing the occurrence of the undercut and improving the linearity of the resist pattern outline and the resolution, it is preferable that R¹⁴ is a hydrogen atom, and from the viewpoint of further improving the thermal shock resistance, it is preferable that Y⁶ is a glycidyl group. n₂ indicates 1 or more, and may be 10 to 100, 10 to 80, or 15 to 60. In a case where n₂ is in the range described above, the linearity of the resist pattern outline, the adhesiveness to the copper substrate, and the heat resistance are easily improved.

A bisphenol A-type epoxy resin or a bisphenol F-type epoxy resin, in which in Formula (IV), Y⁶ is a glycidyl group, for example, can be obtained by allowing a hydroxyl group (—OY⁶) of a bisphenol A-type epoxy resin or a bisphenol F-type epoxy resin, in which in Formula (IV), Y⁶ is a hydrogen atom, and epichlorohydrin to react with each other.

In order to accelerate the reaction between the hydroxyl group and the epichlorohydrin, it is preferable to perform the reaction in a polar organic solvent such as dimethyl formamide, dimethyl acetamide, and dimethyl sulfoxide at a reaction temperature of 50 to 120° C. in the presence of an alkali metal hydroxide. In a case where the reaction temperature is in the range described above, it is possible to suppress an adverse reaction without excessively slowing down the reaction.

As the bisphenol A-type epoxy resin or the bisphenol F-type epoxy resin represented by Formula (IV′), for example, jER807, jER815, jER825, jER827, jER828, jER834, jER1001, jER1004, jER1007, and jER1009 (Product Names, all are manufactured by Mitsubishi Chemical Corporation), DER-330, DER-301, and DER-361 (Product Names, all are manufactured by The Dow Chemical Company), YD-8125, YDF-170, YDF-175S, YDF-2001, YDF-2004, and YDF-8170 (Product Names, all are manufactured by NIPPON STEEL Chemical & Material Co., Ltd.), and the like are commercially available.

Examples of the epoxy resin (a2) preferably include a triphenol methane-type epoxy resin having a structural unit represented by Formula (V) described below. Examples of the triphenol methane-type epoxy resin having such a structural unit include a triphenol methane-type epoxy resin represented by Formula (V′) described below.

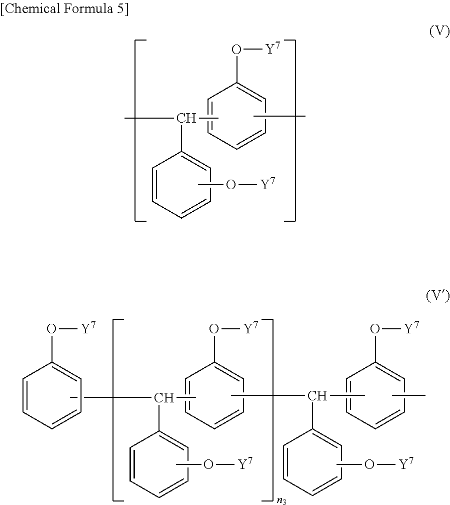

In Formulae (V) and (V′), Y⁷ indicates a hydrogen atom or a glycidyl group, a plurality of Y⁷ may be the same or different from each other, and at least one of Y⁷ is a glycidyl group. In Formula (V′), n₃ indicates a number of 1 or more.

From the viewpoint of suppressing the occurrence of the undercut and upper missing and improving the linearity of the resist pattern outline and the resolution, in Y⁷, a molar ratio of Y⁷, which is a hydrogen atom, to Y⁷, which is a glycidyl group, may be 0/100 to 30/70. As can be seen from such a molar ratio, at least one of Y⁷ is a glycidyl group. n₃ is 1 or more, and may be 10 to 100, 15 to 80, or 15 to 70. In a case where n₃ is in the range described above, the linearity of the resist pattern outline, the adhesiveness to the copper substrate, and the heat resistance are easily improved.

As the triphenol methane-type epoxy resin represented by Formula (V′), for example, FAE-2500, EPPN-501H, and EPPN-502H (Product Names, all are manufactured by Nippon Kayaku Co., Ltd.), and the like are commercially available.

Examples of the epoxy resin (a2) preferably include a biphenyl-type epoxy resin having a structural unit represented by Formula (VI) described below. Examples of the biphenyl-type epoxy resin having such a structural unit include a biphenyl-type epoxy resin represented by Formula (VI′) described below.

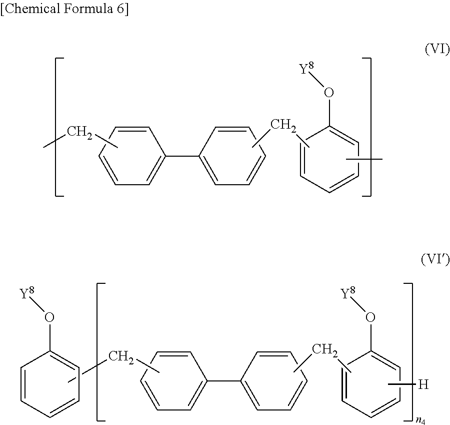

In Formulae (VI) and (VI′), Y⁸ indicates a hydrogen atom or a glycidyl group, a plurality of Y⁸ may be the same or different from each other, and at least one of Y⁸ is a glycidyl group. In Formula (V′), n₄ indicates a number of 1 or more.

As the biphenyl-type epoxy resin represented by Formula (VI′), for example, NC-3000, NC-3000-L, NC-3000-H, NC-3000-FH-75M, NC-3100, and CER-3000-L (Product Names, all are manufactured by Nippon Kayaku Co., Ltd.), and the like are commercially available.

As the epoxy resin (a2), at least one type selected from the group consisting of a novolac-type epoxy resin having a structural unit represented by Formula (III), a bisphenol A-type epoxy resin having a structural unit represented by Formula (IV), and a bisphenol F-type epoxy resin having structural unit represented by Formula (IV) is preferable, and the bisphenol F-type epoxy resin having a structural unit represented by Formula (IV) is more preferable.

From the viewpoint of further improving the thermal shock resistance, warpage reduction properties, and the resolution, the component (A1) using a bisphenol novolac-type epoxy resin having a structural unit represented by Formula (II) as the epoxy resin (a1), and the component (A2) using a bisphenol A-type epoxy resin or a bisphenol F-type epoxy resin having a structural unit represented by Formula (IV) as the epoxy resin (a2) may be used in combination.

Examples of the component (b) include an acrylic acid derivative such as an acrylic acid, a dimer of an acrylic acid, a methacrylic acid, a β-furfuryl acrylic acid, a β-styryl acrylic acid, a cinnamic acid, a crotonic acid, and an α-cyanocinnamic acid; a half-ester compound, which is a reaction product between hydroxyl group-containing (meth)acrylate and a dibasic acid anhydride; and a half-ester compound, which is a reaction product between vinyl group-containing monoglycidyl ether or vinyl group-containing monoglycidyl ester and a dibasic acid anhydride. Only one type of the component (b) may be used, or two or more types thereof may be used in combination.

The half-ester compound, for example, is obtained by allowing hydroxyl group-containing (meth)acrylate, vinyl group-containing monoglycidyl ether, or vinyl group-containing monoglycidyl ester and a dibasic acid anhydride to react with each other.

Examples of the hydroxyl group-containing (meth)acrylate, the vinyl group-containing monoglycidyl ether, and the vinyl group-containing monoglycidyl ester include hydroxyethyl (meth)acrylate, hydroxypropyl (meth)acrylate, hydroxybutyl (meth)acrylate, polyethylene glycol mono(meth)acrylate, trimethylol propane di(meth)acrylate, pentaerythritol tri(meth)acrylate, dipentaerythritol penta(meth)acrylate, and glycidyl (meth)acrylate.

Examples of the dibasic acid anhydride include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride.

In the reaction between the component (a) and the component (b), it is preferable to allow the component (b) to react at a ratio of 0.6 to 1.05 equivalents, and it is more preferable to allow the component (b) to react at a ratio of 0.8 to 1.0 equivalents, with 1 equivalent of the epoxy group of the component (a). By performing the reaction at such a ratio, there is a tendency that optical sensitivity increases, and the linearity of the resist pattern outline is excellent.

The component (a) and the component (b) can be dissolved in an organic solvent to react with each other. Examples of the organic solvent include ketones such as methyl ethyl ketone and cyclohexanone; aromatic hydrocarbon such as toluene, xylene, and tetramethyl benzene; glycol ethers such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; esters such as ethyl acetate, butyl acetate, butyl cellosolve acetate, and carbitol acetate; aliphatic hydrocarbon such as octane and decane; and a petroleum-based solvent such as petroleum ether, petroleum naphtha, hydrogenated petroleum naphtha, and solvent naphtha. Only one type of the organic solvent may be used, or two or more types thereof may be used in combination.

In order to accelerate the reaction between the component (a) and the component (b), a catalyst may be used. Examples of the catalyst include triethyl amine, benzyl methyl amine, methyl triethyl ammonium chloride, benzyl trimethyl ammonium chloride, benzyl trimethyl ammonium bromide, benzyl trimethyl ammonium iodide, and triphenyl phosphine. Only one type of the catalyst may be used, or two or more types thereof may be used in combination.

From the viewpoint of accelerating the reaction between the component (a) and the component (b), the used amount of the catalyst may be 0.01 to 10 parts by mass, 0.05 to 2 parts by mass, or 0.1 to 1 parts by mass, with respect to 100 parts by mass of the total amount of the component (a) and the component (b).

In order to prevent polymerization during the reaction, a polymerization inhibitor may be used in the reaction between the component (a) and the component (b). Examples of the polymerization inhibitor include hydroquinone, methyl hydroquinone, hydroquinone monomethyl ether, catechol, and pyrogallol. Only one type of the polymerization inhibitor may be used, or two or more types thereof may be used in combination.

From the viewpoint of improving stability, the used amount of the polymerization inhibitor may be 0.01 to 1 parts by mass, 0.02 to 0.8 parts by mass, or 0.04 to 0.5 parts by mass, with respect to 100 parts by mass of the total amount of the component (a) and the component (b).

From the viewpoint of productivity, the reaction temperature of the component (a) and the component (b) may be 60 to 150° C., 80 to 120° C., or 90 to 110° C.

The component (A′) obtained by allowing the component (a) and the component (b) to react with each other has a hydroxyl group formed by a ring-opening addition reaction between the epoxy group of the component (a) and the carboxy group of the component (b). By allowing the component (c) to further react with component (A′), an acid-modified vinyl group-containing resin is obtained in which the hydroxyl group of the component (A′) (also including a hydroxyl group that originally exists in the component (a)) and the acid anhydride group of the component (c) are half-esterified.

Examples of the component (c) include a succinic anhydride, a maleic anhydride, a tetrahydrophthalic anhydride, a phthalic anhydride, a methyl tetrahydrophthalic anhydride, an ethyl tetrahydrophthalic anhydride, a hexahydrophthalic anhydride, a methyl hexahydrophthalic anhydride, an ethyl hexahydrophthalic anhydride, and an itaconic anhydride. Among them, the tetrahydrophthalic anhydride is preferable from the viewpoint of the resolution. Only one type of the component (c) may be used, or two or more types thereof may be used in combination.

In the reaction between the component (A′) and the component (c), for example, by allowing the component (c) to react at 0.1 to 1.0 equivalents, with 1 equivalent of the hydroxyl group in the component (A′), it is possible to adjust the acid value of the component (A).

From the viewpoint of the productivity, the reaction temperature of the component (A′) and the component (c) may be 50 to 150° C., 60 to 120° C., or 70 to 100° C.

As necessary, as the component (a), a part of a hydrogenated bisphenol A-type epoxy resin may be used together, or a part of a styrene-maleic acid-based resin such as modified hydroxyethyl (meth)acrylate of a styrene-maleic anhydride copolymer may be used together.

From the viewpoint of suppressing the occurrence of the undercut and further improving the adhesiveness to the copper substrate, the thermal shock resistance, and the resolution, it is preferable that the component (A) contains the component (A1), and in particular, from the viewpoint of improving an adhesive strength, it is more preferable that the component (A) contains the component (A1) and the component (A2). In a case where the component (A1) and the component (A2) are used in combination as the component (A), a mass ratio of (A1)/(A2) is not particularly limited, and may be 20/80 to 90/10, 30/70 to 80/20, 40/60 to 75/25, or 50/50 to 70/30, from the viewpoint of improving the linearity of the resist pattern outline, electroless plating resistance, and the heat resistance.

The acid value of the component (A) is not particularly limited. The acid value of the component (A) may be 30 mgKOH/g or more, 40 mgKOH/g or more, or 50 mgKOH/g or more, from the viewpoint of improving the solubility of an unexposed portion to an alkali aqueous solution. The acid value of the component (A) may be 150 mgKOH/g or less, 120 mgKOH/g or less, or 100 mgKOH/g or less, from the viewpoint of improving the electric properties of the cured film.

The weight average molecular weight (Mw) of the component (A) is not particularly limited. From the viewpoint of improving the adhesiveness of the cured film, Mw of the component (A) may be 3000 or more, 4000 or more, or 5000 or more. From the viewpoint of improving the resolution of a photosensitive layer, Mw of the component (A) may be 30000 or less, 25000 or less, or 18000 or less.

Mw can be measured by a gel permeation chromatography (GPC) method. Mw, for example, can be a value measured in the following GPC condition and converted by using a calibration curve of standard polystyrene. The calibration curve can be created by using five sample sets (“PStQuick MP-H” and “PStQuick B”, manufactured by Tosoh Corporation) as standard polystyrene.

GPC device: a high-speed GPC device “HCL-8320GPC” (manufactured by Tosoh Corporation)

Detector: a differential refractometer or a UV detector (manufactured by Tosoh Corporation)

Column: column TSKgel SuperMultipore HZ-H (column length: 15 cm, column inner diameter: 4.6 mm) (manufactured by Tosoh Corporation)

Eluent: tetrahydrofuran (THF)

Measurement temperature: 40° C.

Flow rate: 0.35 mL/minute

Sample concentration: 10 mg/THF 5 mL

Injection amount: 20 μL

From the viewpoint of improving the heat resistance, the electric properties, and the chemical resistance of the permanent resist, the content of the component (A) in the photosensitive resin composition may be 20 to 70% by mass, 25 to 60% by mass, 28 to 50% by mass, or to 45% by mass, on the basis of the total solid content of the photosensitive resin composition.

(Component (B): Thermosetting Resin)

In the photosensitive resin composition according to this embodiment, by using the thermosetting resin as the component (B), it is possible to improve the heat resistance, the bonding adhesiveness, and the chemical resistance of the cured film (the permanent resist) formed from the photosensitive resin composition. Only one type of the component (B) may be used, or two or more types thereof may be used in combination.

Examples of the component (B) include an epoxy resin, a phenolic resin, an unsaturated imide resin, a cyanate resin, an isocyanate resin, a benzooxazine resin, an oxetane resin, an amino resin, an unsaturated polyester resin, an allyl resin, a dicyclopentadiene resin, a silicone resin, a triazine resin, and a melamine resin.

Examples of the epoxy resin include a bisphenol A-type epoxy resin, a bisphenol F-type epoxy resin, a hydrogenated bisphenol A-type epoxy resin, a brominated bisphenol A-type epoxy resin, a bisphenol S-type epoxy resin, a novolac-type epoxy resin, a biphenyl-type epoxy resin, a naphthalene-type epoxy resin, a dicyclopentadiene-type epoxy resin, a hydantoin-type epoxy resin, a triglycidyl isocyanurate, and a bixylenol-type epoxy resin.

The content of the component (B) may be 2 to 30% by mass, 5 to 25% by mass, 6 to 22% by mass, or 8 to 20% by mass, on the basis of the total solid content of the photosensitive resin composition. In a case where the content of the component (B) is in the range described above, it is possible to further improve the heat resistance of the cured film to be formed while maintaining excellent developability.

(Component (C): Photopolymerization Initiator)

The photopolymerization initiator, which is the component (C), is not particularly limited insofar as the photopolymerization initiator is capable of polymerizing the component (A) and the component (D). Only one type of the component (C) may be used, or two or more types thereof may be used in combination.

Examples of the component (C) include a benzoin compound such as benzoin, benzoin methyl ether, and benzoin isopropyl ether; an acetophenone compound such as acetophenone, 2,2-dimethoxy-2-phenyl acetophenone, 2,2-diethoxy-2-phenyl acetophenone, 1,1-dichloroacetophenone, 1-hydroxycyclohexyl phenyl ketone, 2-benzyl-2-dimethyl amino-1-(4-morpholinophenyl)-butanone-1, 2-methyl-[4-(methyl thio)phenyl]-2-morpholino-1-propane, and N,N-dimethyl aminoacetophenone; an anthraquinone compound such as 2-methyl anthraquinone, 2-ethyl anthraquinone, 2-tert-butyl anthraquinone, 1-chloroanthraquinone, 2-amyl anthraquinone, and 2-aminoanthraquinone; a thioxanthene compound such as 2,4-dimethyl thioxanthene, 2,4-diethyl thioxanthene, 2-chlorothioxanthene, and 2,4-diisopropyl thioxanthene; a ketal compound such as acetophenone dimethyl ketal and benzyl dimethyl ketal; a benzophenone compound such as benzophenone, methyl benzophenone, 4,4′-dichlorobenzophenone, 4,4′-bis(diethyl amino)benzophenone, Michler's ketone, and 4-benzoyl-4′-methyl diphenyl sulfide; an imidazole compound such as a 2-(o-chlorophenyl)-4,5-diphenyl imidazole dimer, a 2-(o-chlorophenyl)-4,5-di(m-methoxyphenyl) imidazole dimer, a 2-(o-fluorophenyl)-4,5-diphenyl imidazole dimer, a 2-(o-methoxyphenyl)-4,5-diphenyl imidazole dimer, a 2-(p-methoxyphenyl)-4,5-diphenyl imidazole dimer, a 2,4-di(p-methoxyphenyl)-5-phenyl imidazole dimer, and a 2-(2,4-dimethoxyphenyl)-4,5-diphenyl imidazole dimer; an acridine compound such as 9-phenyl acridine and 1,7-bis(9,9′-acridinyl) heptane; an acyl phosphine oxide compound such as 2,4,6-trimethyl benzoyl diphenyl phosphine oxide; an oxime ester compound such as 1,2-octanedione-1-[4-(phenyl thio)phenyl]-2-(O-benzoyl oxime), 1-[9-ethyl-6-(2-methyl benzoyl)-9H-carbazol-3-yl] ethanone 1-(O-acetyl oxime), and 1-phenyl-1,2-propanedione-2[O-(ethoxycarbonyl) oxime]; and a tertiary amine compound such as ethyl N,N-dimethyl aminobenzoic acid ester, isoamyl N,N-dimethyl aminobenzoic acid ester, pentyl-4-dimethyl aminobenzoate, triethyl amine, and triethanol amine.

The content of the component (C) in the photosensitive resin composition is not particularly limited, and may be 0.2 to 15% by mass, 0.5 to 10% by mass, 0.8 to 5% by mass, or 1 to 3% by mass, on the basis of the total solid content of the photosensitive resin composition.

(Component (D): Photopolymerizable Compound)

In the photosensitive resin composition according to this embodiment, by using the photopolymerizable compound having a polyoxyalkylene chain and an ethylenically unsaturated group as the component (D), it is possible to improve the resolution and the pattern forming properties of the photosensitive resin composition, and to form the permanent resist excellent in the thermal shock resistance. The component (D) is a photopolymerizable compound not having an acid group. Only one type of the component (D) may be used, or two or more types thereof may be used in combination.

The polyoxyalkylene chain has two or more oxyalkylene groups. A plurality of oxyalkylene groups configuring the polyoxyalkylene chain may be the same or different from each other. The polyoxyalkylene chain may be a random copolymer in which two or more types of oxyalkylene groups are irregularly arranged, or may be a block copolymer including a block in which the same oxyalkylene groups are continuously bonded. The polyoxyalkylene chain, for example, can be derived from polyether such as polyalkylene glycol. Examples of the polyoxyalkylene chain include a polyoxyethylene chain, a polyoxypropylene chain, and a polyoxybutylene chain. Note that, “(EO)-modified” indicates having a polyoxyethylene chain, and “(PO)-modified” indicates having a polyoxypropylene chain.

The ethylenically unsaturated group is not particularly limited insofar as the ethylenically unsaturated group has photopolymerizability, and from the viewpoint of the reactivity and the resolution, a (meth)acryloyl group is preferable.

Examples of the component (D) include an alkylene oxide-modified (meth)acrylate compound, an alkylene oxide-modified bisphenol A-type (meth)acrylate compound, an alkylene oxide-modified bisphenol F-type (meth)acrylate compound, an alkylene oxide-modified ditrimethylol propane (meth)acrylate compound, an alkylene oxide-modified dipentaerythritol (meth)acrylate compound, an alkylene oxide-modified pentaerythritol (meth)acrylate compound, an alkylene oxide-modified trimethylol propane (meth)acrylate compound, an alkylene oxide-modified diglycerin (meth)acrylate compound, and an alkylene oxide-modified glycerin (meth)acrylate compound.

From the viewpoint of improving chemical resistance, the alkylene oxide-modified (meth)acrylate compound, the alkylene oxide-modified trimethylol propane, the alkylene oxide-modified pentaerythritol (meth)acrylate compound, the alkylene oxide-modified dipentaerythritol (meth)acrylate compound, the alkylene oxide-modified ditrimethylol propane (meth)acrylate compound, the alkylene oxide-modified bisphenol A-type (meth)acrylate compound, or the alkylene oxide-modified bisphenol F-type (meth)acrylate compound is preferable, from the viewpoint of further improving the resolution, the alkylene oxide-modified (meth)acrylate compound, the alkylene oxide-modified bisphenol A-type (meth)acrylate compound, or the alkylene oxide-modified bisphenol F-type (meth)acrylate compound is more preferable, and from the viewpoint of imparting flexibility, the alkylene oxide-modified (meth)acrylate compound is even more preferable.

The number of oxyalkylene groups in the polyoxyalkylene chain (the number of oxyalkylene groups in one molecule) may be 2 to 50, and is preferably 8 to 40, more preferably 10 to 35, even more preferably 10 to 30, and particularly preferably 12 to 20, from the viewpoint of further improving the resolution, the flexibility, the heat resistance, the thermal shock resistance, and insulating properties.

From the viewpoint of forming the permanent resist excellent in the heat resistance and the thermal shock resistance while exhibiting higher resolution and an excellent resist pattern shape, the content of the component (D) in the photosensitive resin composition may be 1 to 15% by mass, 2 to 10% by mass, 3 to 9% by mass, or 4 to 8% by mass, on the basis of the total solid content of the photosensitive resin composition. In a case where the content of the component (D) is 1% by mass or more, optical sensitivity is improved, and an exposed portion is less likely to be eluted during development, and in a case where the content is 15% by mass or less, the heat resistance of the permanent resist is easily improved. The component (D) may further contain a photopolymerizable compound not having a polyoxyalkylene chain. Examples of the photopolymerizable compound not having a polyoxyalkylene chain include a hydroxyalkyl (meth)acrylate compound such as 2-hydroxyethyl (meth)acrylate and 2-hydroxypropyl (meth)acrylate; a (meth)acryl amide compound such as N,N-dimethyl (meth)acryl amide and N-methylol (meth)acryl amide; an aminoalkyl (meth)acrylate compound such as N,N-dimethyl aminoethyl (meth)acrylate; a (meth)acrylate compound of polyhydric alcohol, such as trimethylol propane, pentaerythritol, ditrimethylol propane, dipentaerythritol, and tris-hydroxyethyl isocyanurate; a (meth)acrylate compound of glycidyl ether, such as glycerin diglycidyl ether and triglycidyl isocyanurate; and a melamine (meth)acrylate compound. It is preferable that the molecular weight of the photopolymerizable compound not having a polyoxyalkylene chain is 1000 or less, from the viewpoint of the optical sensitivity.

(Component (E): Inorganic Filler)

The photosensitive resin composition according to this embodiment may further contain an inorganic filler as a component (E). By containing the component (E), it is possible to improve the bonding adhesive strength and the hardness of the permanent resist. Only one type of the component (E) may be used, or two or more types thereof may be used in combination.

Examples of the inorganic filler include silica, alumina, titania, tantalum oxide, zirconia, silicon nitride, barium titanate, barium carbonate, magnesium carbonate, aluminium hydroxide, magnesium hydroxide, lead titanate, lead zirconate titanate, lanthanum lead zirconate titanate, gallium oxide, spinel, mullite, cordierite, talc, aluminum titanate, yttria-containing zirconia, barium silicate, boron nitride, calcium carbonate, barium sulfate, calcium sulfate, zinc oxide, magnesium titanate, hydrotalcite, mica, calcined kaolin, and carbon.

From the viewpoint of improving the heat resistance of the permanent resist, the component (E) may contain silica, and from the viewpoint of improving the heat resistance and the bonding adhesive strength of the permanent resist, the component (E) may contain barium sulfate, or may contain silica and barium sulfate. From the viewpoint of improving the dispersibility of the inorganic filler, an inorganic filler of which the surface is treated in advance with alumina or an organic silane compound may be used.

From the viewpoint of the resolution, the average particle diameter of the inorganic filler may be 0.01 to 5.0 μm, 0.05 to 3.0 μm, 0.1 to 2.0 μm, or 0.15 to 1.0 μm.

The average particle diameter of the component (E) is the average particle diameter of the inorganic filler in the state of being dispersed in the photosensitive resin composition, and is a value obtained by being measured as follows. First, the photosensitive resin composition is diluted 1000 times with methyl ethyl ketone, and then, particles dispersed in a solvent are measured at a refractive index of 1.38 by using a submicron particle analyzer (Product Name: N5, manufactured by Beckman Coulter, Inc.), on the basis of International Organization for Standardization ISO13321, and a particle diameter at an integrated value of 50% (volume basis) in a particle size distribution is set as the average particle diameter.

The content of the component (E) may be 5 to 70% by mass, 6 to 60% by mass, 10 to 50% by mass, 15 to 45% by mass, or 20 to 40% by mass, on the basis of the total solid content of the photosensitive resin composition. In a case where the content of the component (E) is in the range described above, it is possible to further improve a low coefficient of thermal expansion, the heat resistance, and the film strength.

In a case where silica is used as the component (E), the content of the silica may be 5 to 60% by mass, 10 to 55% by mass, or 15 to 50% by mass, on the basis of the total solid content of the photosensitive resin composition. In a case where barium sulfate is used as the component (E), the content of the barium sulfate may be 5 to 30% by mass, 5 to 25% by mass, or 10 to 20% by mass, on the basis of the total solid content of the photosensitive resin composition. In a case where the content of the silica and the barium sulfate is in the range described above, there is a tendency that the low coefficient of thermal expansion, solder heat resistance, and the bonding adhesive strength are excellent.

(Component (F): Pigment)

From the viewpoint of improving the identifiability or the appearance of a production apparatus, the photosensitive resin composition according to this embodiment may further contain a pigment as a component (F). As the component (F), a coloring agent for developing a desired color when hiding wiring (a conductor pattern) can be used. Only one type of the component (F) may be used, or two or more types thereof may be used in combination.

Examples of the component (F) include Phtalocyanine Blue, Phtalocyanine Green, Iodine Green, Diazo Yellow, Crystal Violet, Titanium Oxide, Carbon Black, and Naphthalene Black.

From the viewpoint of easily identifying the production apparatus and further hiding the wiring, the content of the component (F) may be 0.01 to 5.0% by mass, 0.03 to 3.0% by mass, or 0.05 to 2.0% by mass, on the basis of the total solid content of the photosensitive resin composition.

(Component (G): Ion Scavenger)

From the viewpoint of improving a resist shape, the adhesiveness, fluidity, and reliability, the photosensitive resin composition according to this embodiment may further contain an ion scavenger as a component (G). The component (G) is not particularly limited insofar as the component is capable of scavenging ions in the ion scavenger and has a function of scavenging at least one of cations and anions.

In this embodiment, the ions to be scavenged, for example, are ions such as sodium ions (Na⁺), chlorine ions (Cl⁻), bromine ions (Br⁻), and copper ions (Cu⁺, Cu²⁺), which are incorporated in a composition reacting by the irradiation of an electron beam, or the like to change the degree of solubility with respect to a solvent. By scavenging such ions, the electrical insulating properties, electric corrosion resistance, and the like are improved.

It is preferable that the component (G) is an ion scavenger having at least one type selected from the group consisting of zirconium (Zr), bismuth (Bi), magnesium (Mg), and aluminum (Al). Only one type of the component (G) may be used, or two or more types thereof may be used in combination.

Examples of the component (G) include a cation scavenger scavenging cations, an anion scavenger scavenging anions, and an ampholyte ion scavenger scavenging cations and anions.

Examples of the cation scavenger include an inorganic ion exchanger of a metal oxide such as zirconium phosphate, zirconium tungstate, zirconium molybdate, zirconium tungstate, zirconium antimonate, zirconium selenate, zirconium tellurate, zirconium silicate, zirconium phosphosilicate, and polyzirconium phosphate.

Examples of the anion scavenger include an inorganic ion exchanger such as a bismuth oxide hydrate and hydrotalcites.

Examples of the ampholyte ion scavenger include an inorganic ion exchanger of a hydrous metal oxide such as an aluminum oxide hydrate and a zirconium oxide hydrate. As the ampholyte ion scavenger, IXE-1320 (a Mg, Al-containing compound), IXE-600 (a Bi-containing compound), IXE-633 (a Bi-containing compound), IXE-680 (a Bi-containing compound), IXE-6107 (a Zr, Bi-containing compound), IXE-6136 (a Zr, Bi-containing compound), IXEPLAS-A1 (a Zr, Mg, Al-containing compound), IXEPLAS-A2 (a Zr, Mg, Al-containing compound), and IXEPLAS-B1 (a Zr, Bi-containing compound), which are manufactured by TOAGOSEI CO., LTD., and the like are commercially available.

The component (G) can be in the shape of particles, and from the viewpoint of improving the insulating properties, the average particle diameter of the component (G) may be 5 μm or less, 3 μm or less, or 2 μm or less, and may be 0.1 μm or more. The average particle diameter of the component (G) is the particle diameter of the particles in the state of being dispersed in the photosensitive resin composition, and can be measured by the same method as the measurement method of the average particle diameter of the component (E).

In a case where the photosensitive resin composition of this embodiment contains the component (G), the content thereof is not particularly limited, and may be 0.05 to 10% by mass, 0.1 to 5% by mass, or 0.2 to 1% by mass, on the basis of the total solid content of the photosensitive resin composition, from the viewpoint of improving the electrical insulating properties and the electric corrosion resistance.

(Component (H): Elastomer)

The photosensitive resin composition according to this embodiment may further contain an elastomer as a component (H). By containing the component (H), it is possible to suppress a decrease in the flexibility and the bonding adhesive strength, which is caused by strain (internal stress) in a resin due to the curing contraction of the component (A).

Examples of the component (H) include a styrene-based elastomer, an olefin-based elastomer, a urethane-based elastomer, a polyester-based elastomer, a polyamide-based elastomer, an acrylic elastomer, and a silicone-based elastomer. Such an elastomer contains a hard segment component contributing to the heat resistance and the strength, and a soft segment component contributing to the flexibility and toughness. Among them, the olefin-based elastomer and the polyester-based elastomer are preferable.

Examples of the styrene-based elastomer include a styrene-butadiene-styrene block copolymer, a styrene-isoprene-styrene block copolymer, a styrene-ethylene-butylene-styrene block copolymer, and a styrene-ethylene-propylene-styrene block copolymer. As the component configuring the styrene-based elastomer, a styrene derivative such as α-methyl styrene, 3-methyl styrene, 4-propyl styrene, and 4-cyclohexyl styrene can be used, in addition to styrene.

Examples of the olefin-based elastomer include an ethylene-propylene copolymer, an ethylene-α-olefin copolymer, an ethylene-α-olefin-unconjugated diene copolymer, a propylene-α-olefin copolymer, a butene-α-olefin copolymer, an ethylene-propylene-diene copolymer, a copolymer of unconjugated diene such as dicyclopentadiene, 1,4-hexadiene, cyclooctadiene, methylene norbornene, ethylidene norbornene, butadiene, and isoprene, and α-olefin, epoxy-modified polybutadiene, and a carboxylic acid-modified butadiene-acrylonitrile copolymer.

It is preferable that the epoxy-modified polybutadiene has a hydroxyl group on a molecular terminal, it is more preferable that the epoxy-modified polybutadiene has a hydroxyl group on both molecular terminals, and it is even more preferable that the epoxy-modified polybutadiene has a hydroxyl group only on both molecular terminals. The number of hydroxyl groups of the epoxy-modified polybutadiene may be 1 or more, and is preferably 1 to 5, more preferably 1 or 2, and even more preferably 2.

As the urethane-based elastomer, a compound including a hard segment containing low-molecular (short-chain) diol and diisocyanate and a soft segment containing high-molecular (long-chain) diol and diisocyanate can be used.

Examples of the short-chain diol include ethylene glycol, propylene glycol, 1,4-butanediol, and bisphenol A. It is preferable that the number average molecular weight of the short-chain diol is 48 to 500.

Examples of the long-chain diol include polypropylene glycol, polytetramethylene oxide, poly(1,4-butylene adipate), poly(ethylene-1,4-butylene adipate), polycaprolactone, poly(1,6-hexylene carbonate), and poly(1,6-hexylene-neopentylene adipate). It is preferable that the number average molecular weight of the long-chain diol is 500 to 10000.

As the polyester-based elastomer, a compound obtained by polycondensing a dicarboxylic acid or a derivative thereof and a diol compound or a derivative thereof can be used.

Examples of the dicarboxylic acid include an aromatic dicarboxylic acid such as a terephthalic acid, an isophthalic acid, and a naphthalene dicarboxylic acid; an aliphatic dicarboxylic acid having 2 to carbon atoms, such as an adipic acid, a sebacic acid, and a dodecane dicarboxylic acid; and an alicyclic dicarboxylic acid such as a cyclohexane dicarboxylic acid. Only one type of the dicarboxylic acid can be used, or two or more types can be used in combination.

Examples of the diol compound include aliphatic diol such as ethylene glycol, 1,3-propanediol, 1,4-butanediol, 1,6-hexanediol, and 1,10-decanediol; alicyclic diol such as 1,4-cyclohexanediol; and aromatic diol such as bisphenol A, bis-(4-hydroxyphenyl) methane, bis-(4-hydroxy-3-methyl phenyl) propane, and resorcin.

As the polyester-based elastomer, a multi-block copolymer containing aromatic polyester (for example, polybutylene terephthalate) as a hard segment component and aliphatic polyester (for example, polytetramethylene glycol) as a soft segment component can be used. There are various grades of polyester-based elastomers, in accordance with a difference between the types, the ratios, and the molecular weights of the hard segment and the soft segment.

The polyamide-based elastomer is broadly classified into two types of a polyether block amide type and a polyether ester block amide type using polyamide in a hard segment and polyether or polyester in a soft segment. Examples of the polyamide include polyamide-6, polyamide-11, and polyamide-12. Examples of the polyether include polyoxyethylene glycol, polyoxypropylene glycol, and polytetramethylene glycol.

As the acrylic elastomer, a compound containing a constituent unit based on (meth)acrylic acid ester as a main component can be used. Examples of the (meth)acrylic acid ester include methyl (meth)acrylate, ethyl (meth)acrylate, butyl (meth)acrylate, methoxy ethyl (meth)acrylate, and ethoxy ethyl (meth)acrylate. The acrylic elastomer may be a compound obtained by copolymerizing (meth)acrylic acid ester and acrylonitrile, or may be a compound obtained by further copolymerizing a monomer having a functional group to be a crosslinking point. Examples of the monomer having a functional group include glycidyl methacrylate and allyl glycidyl ether.

Examples of the acrylic elastomer include an acrylonitrile-butyl acrylate copolymer, an acrylonitrile-butyl acrylate-ethyl acrylate copolymer, a methyl methacrylate-butyl acrylate-methacrylic acid copolymer, and an acrylonitrile-butyl acrylate-glycidyl methacrylate copolymer. As the acrylic elastomer, the acrylonitrile-butyl acrylate-glycidyl methacrylate copolymer or the methyl methacrylate-butyl acrylate-methacrylic acid copolymer is preferable, and the methyl methacrylate-butyl acrylate-methacrylic acid copolymer is more preferable.

The silicone-based elastomer is a compound containing organopolysiloxane as a main component. Examples of the organopolysiloxane include polydimethyl siloxane, polymethyl phenyl siloxane, and polydiphenyl siloxane. The silicone-based elastomer may be a compound obtained by modifying a part of the organopolysiloxane with a vinyl group, an alkoxy group, or the like.

From the viewpoint of improving the adhesiveness of the cured film, the component (H) may include a carboxylic acid-modified butadiene-acrylonitrile copolymer or a polyester-based elastomer having a hydroxyl group.

The content of the component (H) may be 2 to 40 parts by mass, 4 to 30 parts by mass, 6 to 20 parts by mass, or 10 to 15 parts by mass, with respect to 100 parts by mass of the component (A). In a case where the content of the component (H) is in the range described above, an elastic modulus in a high-temperature region of the cured film decreases, and the unexposed portion is more easily eluted by a developer.

(Other Components)

In the photosensitive resin composition according to this embodiment, as necessary, various additives may be further contained. Examples of the additives include a polymerization inhibitor such as hydroquinone, methyl hydroquinone, hydroquinone monomethyl ether, catechol, and pyrogallol; a thickener such as bentone and montmorillonite; a silicone-based defoamer, a fluorine-based defoamer, and a vinyl resin-based defoamer; a silane coupling agent; and a flame retardant such as a brominated epoxy compound, an acid-modified brominated epoxy compound, an antimony compound, a phosphate compound, condensed aromatic phosphate ester, and condensed halogen-containing phosphate ester.

(Solvent)

Since the photosensitive resin composition according to this embodiment contains a solvent for dissolving and dispersing each component, it is possible to facilitate the coating onto the substrate and form a coated film with a homogeneous thickness.

Examples of the solvent include ketone such as methyl ethyl ketone and cyclohexanone; aromatic hydrocarbon such as toluene, xylene, and tetramethyl benzene; glycol ether such as methyl cellosolve, butyl cellosolve, methyl carbitol, butyl carbitol, propylene glycol monomethyl ether, dipropylene glycol monoethyl ether, dipropylene glycol diethyl ether, and triethylene glycol monoethyl ether; ester such as ethyl acetate, butyl acetate, butyl cellosolve acetate, and carbitol acetate; aliphatic hydrocarbon such as octane and decane; and a petroleum-based solvent such as petroleum ether, petroleum naphtha, hydrogenated petroleum naphtha, and solvent naphtha. Only one type of the solvent may be used, or two or more types thereof may be used in combination.

The compound amount of the solvent is not particularly limited, and the ratio of the solvent to the photosensitive resin composition may be 10 to 50% by mass, 20 to 40% by mass, or 25 to 35% by mass.

The photosensitive resin composition of this embodiment can be prepared by homogeneously mixing each component described above with a roll mill, a bead mill, or the like.

[Photosensitive Element]

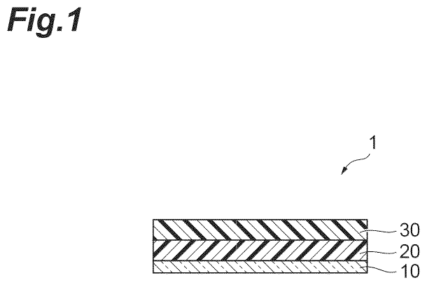

A photosensitive element according to this embodiment includes a support film, and a photosensitive layer containing the photosensitive resin composition described above. FIG. 1 is a sectional view schematically illustrating the photosensitive element according to this embodiment. As illustrated in FIG. 1, a photosensitive element 1 includes a support film 10, and a photosensitive layer 20 formed on the support film 10.

The photosensitive element 1 can be produced by applying the photosensitive resin composition according to this embodiment onto the support film 10 using a known method such as reverse roll coating, gravure roll coating, comma coating, and curtain coating, and then, drying the coated film to form the photosensitive layer 20.

Examples of the support film include a polyester film such as polyethylene terephthalate and polybutylene terephthalate, and a polyolefin film such as polypropylene and polyethylene. The thickness of the support film, for example, may be 5 to 100 μm. The thickness of the photosensitive layer, for example, may be 5 to 50 μm, 5 to 40 μm, or to 30 μm. The surface roughness of the support film is not particularly limited, and arithmetic average roughness (Ra) may be 1000 nm or less, 500 nm or less, or 250 nm or less.

In the drying of the coated film, hot-air drying, and drying using a far infrared ray or a near infrared ray can be used. A drying temperature may be 60 to 120° C., 70 to 110° C., or 80 to 100° C. A drying time may be 1 to 60 minutes, 2 to 30 minutes, or 5 to 20 minutes.

A protective film 30 for covering the photosensitive layer 20 may be further provided on the photosensitive layer 20. In the photosensitive element 1, the protective film 30 can also be laminated on the surface of the photosensitive layer 20 on a side opposite to the surface in contact with the support film 10. As the protective film 30, for example, a polymer film such as polyethylene and polypropylene may be used.

[Printed Wiring Board]

A printed wiring board according to this embodiment includes a permanent resist containing a cured material of the photosensitive resin composition according to this embodiment.

A method for producing a printed wiring board according to this embodiment includes a step of forming a photosensitive layer on a substrate by using the photosensitive resin composition or the photosensitive element described above, a step of forming a resist pattern by exposing and developing the photosensitive layer, a step of forming a permanent resist by curing the resist pattern. Hereinafter, an example of each step will be described.

First, the substrate such as a copper-clad laminate is prepared, and the photosensitive layer is formed on the substrate. The photosensitive layer may be formed by applying the photosensitive resin composition onto the substrate and drying the photosensitive resin composition. Examples of a method for applying the photosensitive resin composition include a screen printing method, a spraying method, a roll coating method, a curtain coating method, and an electrostatic coating method. A drying temperature may be 60 to 120° C., 70 to 110° C., or 80 to 100° C. A drying time may be 1 to 7 minutes, 1 to 6 minutes, or 2 to 5 minutes.

The photosensitive layer may be formed by peeling off the protective film from the photosensitive element and laminating the photosensitive layer on the substrate. Examples of a method for laminating the photosensitive layer include a method for thermally laminating the photosensitive layer by using a laminator.

Next, a negative film is directly brought into contact with the photosensitive layer or is brought into contact with the photosensitive layer through the support film, and is irradiated with an active light ray to be exposed. Examples of the active light ray include an electron beam, an ultraviolet ray, and an X-ray, and the ultraviolet ray is preferable. As a light source, a low-pressure mercury lamp, a high-pressure mercury lamp, an ultrahigh-pressure mercury lamp, a halogen lamp, and the like can be used. An exposed amount may be 10 to 2000 mJ/cm², 100 to 1500 mJ/cm², or 300 to 1000 mJ/cm².

After the exposure, the unexposed portion is removed by a developer to form the resist pattern. Examples of a developing method include a dipping method and a spraying method. As the developer, for example, an alkali aqueous solution such as potassium hydroxide, sodium hydroxide, sodium carbonate, potassium carbonate, and tetramethyl ammonium hydroxide can be used.

It is possible to form a pattern cured film (the permanent resist) by treating the resist pattern with at least one of post exposure and post heating. The exposed amount of the post exposure may be 100 to 5000 mJ/cm², 500 to 2000 mJ/cm², or 700 to 1500 J/cm². The heating temperature of the post heating may be 100 to 200° C., 120 to 180° C., or 135 to 165° C. The heating time of the post heating may be 5 minutes to 12 hours, 10 minutes to 6 hours, or 30 minutes to 2 hours.

A permanent resist according to this embodiment can be used as an interlayer insulating layer or a surface protective layer of a semiconductor element. It is possible to produce a semiconductor element provided with the interlayer insulating layer or the surface protective layer formed from the cured film of the photosensitive resin composition described above, and an electronic device including the semiconductor element. The semiconductor element, for example, may be a memory, a package, or the like, having a multilayer wiring structure, a rewiring structure, or the like. Examples of the electronic device include a mobile phone, a smart phone, a tablet-type terminal, a personal computer, and a hard disk suspension. By including the pattern cured film formed from the photosensitive resin composition according to this embodiment, it is possible to provide the semiconductor element and the electronic device excellent in the reliability.

### EXAMPLES

Hereinafter, the present disclosure will be described in more detail by examples, but the present disclosure is not limited to those examples.

### Synthesis Example 1

350 parts by mass of a bisphenol F novolac-type epoxy resin (Product Name: “EXA-7376”, manufactured by DIC Corporation, a bisphenol F novolac-type epoxy resin having a structural unit in which in Formula (II), Y³ and Y⁴ are a glycidyl group, and R¹² is a hydrogen atom, Epoxy Equivalent: 186), 70 parts by mass of an acrylic acid, 0.5 parts by mass of methyl hydroquinone, and 120 parts by mass of carbitol acetate were mixed while stirring at 90° C. The mixed liquid was cooled to 60° C., and 2 parts by mass of triphenyl phosphine was added to react until the acid value of the solution was 1 mgKOH/g or less at 100° C. 98 parts by mass of a tetrahydrophthalic anhydride (THPAC) and 85 parts by mass of carbitol acetate were added to the reaction liquid to react at 80° C. for 6 hours. After that, the reaction liquid was cooled to a room temperature to obtain a solution (Solid Content Concentration: 73% by mass) of acid-modified epoxy acrylate (A-1) as a component (A).

### Synthesis Example 2

1052 parts by mass of a bisphenol F-type epoxy resin (a bisphenol F-type epoxy resin having a structural unit in which in Formula (IV), Y⁶ is a hydrogen atom, and R¹⁴ is a hydrogen atom, Epoxy Equivalent: 526), 144 parts by mass of an acrylic acid, 1 part by mass of methyl hydroquinone, 850 parts by mass of carbitol acetate, and 100 parts by mass of solvent naphtha were mixed while stirring at 70° C. The mixed liquid was cooled to 50° C., and 2 parts by mass of triphenyl phosphine and 75 parts by mass of solvent naphtha were added to react until the acid value of the solution was 1 mgKOH/g or less at 100° C. The reaction liquid was cooled to 50° C., and then, 745 parts by mass of THPAC, 75 parts by mass of carbitol acetate, and 75 parts by mass of solvent naphtha were added to react at 80° C. for 6 hours. After that, the reaction liquid was cooled to a room temperature to obtain a solution (Solid Content Concentration: 62% by mass) of acid-modified epoxy acrylate (A-2) as a component (A).

The following materials were prepared as components (B) to (H).
B-1: a tetramethyl bisphenol F-type epoxy resin (Product Name: “YSLV-80XY”, manufactured by NIPPON STEEL Chemical & Material Co., Ltd.)
B-2: a novolac-type polyfunctional epoxy resin (Product Name: “RE-306”, manufactured by Nippon Kayaku Co., Ltd.)
C-1: 2-methyl-[4-(methyl thio)phenyl] morpholino-1-propanone (Product Name: “Omirad 907”, manufactured by IGM Resins B. V.)
C-2: 2,4-diethyl thioxanthene (Product Name: “DETX-S”, manufactured by Nippon Kayaku Co., Ltd.)
C-3: 4,4′-bis(diethyl amino)benzophenone (EAB)
C-4: ethanone, 1-[9-ethyl-6-(2-methyl benzoyl)-9H-carbazol-3-yl]-, 1-(0-acetyl oxime) (Product Name: “Irgacure OXE02”, manufactured by BASF Japan Ltd.)
D-1: ethoxylated bisphenol A dimethacrylate (Product Name: “BP-2EM”, manufactured by SHIN-NAKAMURA CHEMICAL Co., Ltd., Number of Oxyalkylene Groups: 2.6)
D-2: polyethylene glycol 400 diacrylate (Product Name: “PEG-400DA”, manufactured by SHINNIHON CHEMICALS Corporation, Number of Oxyalkylene Groups: 9)
D-3: EO-modified bisphenol A dimethacrylate (Product Name: “FA-321M”, manufactured by Showa Denko Materials Co., Ltd., Number of Oxyalkylene Groups: 10)
D-4: ethoxylated bisphenol A dimethacrylate (Product Name: “BPE-900”, manufactured by SHIN-NAKAMURA CHEMICAL Co., Ltd., Number of Oxyalkylene Groups: 17)
D-5: (PO)(EO)(PO)-modified dimethacrylate (Product Name: “FA-024M”, manufactured by Showa Denko Materials Co., Ltd., Number of Oxyalkylene Groups: 18)
D-6: ethoxylated pentaerythritol tetramethacrylate (Product Name: “TM-35E”, manufactured by SHIN-NAKAMURA CHEMICAL Co., Ltd., Number of Oxyalkylene Groups: 35)
D-7: methoxy polyethylene glycol methacrylate (Product Name: “M-450G”, manufactured by SHIN-NAKAMURA CHEMICAL Co., Ltd., Number of Oxyalkylene Groups: 45)
D-8: dipentaerythritol hexaacrylate (Product Name: “DPHA”, manufactured by Nippon Kayaku Co., Ltd.)
E-1: silica (Product Name: “SFP20M”, manufactured by Denka Company Limited., Average Particle Diameter: 0.3 μm)
E-2: barium sulfate (Product Name: “B-34”, manufactured by SAKAI CHEMICAL INDUSTRY CO., LTD., Average Particle Diameter: 0.3 μm)
F-1: Phtalocyanine Green (manufactured by SANYO COLOR WORKS, Ltd.)
G-1: a Sb, Bi-based ampholyte ion scavenger (Product Name: “IXE-600”, manufactured by TOAGOSEI CO., LTD., Average Particle Diameter: 1.0 μm)
H-1: epoxidized polybutadiene (Product Name: “PB-3600”, manufactured by Daicel Corporation)
H-2: a thermoplastic polyester elastomer (Product Name: “Hytrel 4057N”, manufactured by DU PONT-TORAY CO., LTD.)

[Photosensitive Resin Composition]

Each component was compounded at a compound amount (parts by mass, a solid content equivalent) shown in Table 1, and kneaded with a triple roll mill. After that, carbitol acetate was added such that the solid content concentration was 70% by mass to prepare a photosensitive resin composition.

[Photosensitive Element]

As a support film, a polyethylene terephthalate film (Product Name: “G2-25”, manufactured by Toyobo Film Solutions Limited) with a thickness of 25 μm was prepared. A solution obtained by diluting the photosensitive resin composition with methyl ethyl ketone was applied onto the support film using a hot-air convention dryer such that a thickness after drying was 25 μm, and dried at 75° C. for 30 minutes to form a photosensitive layer. Next, a polyethylene film (Product Name: “NF-15”, manufactured by TATVJAPOLY CO., LTD.) was pasted onto the surface of the photosensitive layer on a side opposite to the surface in contact with the support film, as a protective film, to obtain a photosensitive element.

(Resolution)

A copper-clad laminate (Product Name: “MCL-E-67”, manufactured by Showa Denko Materials Co., Ltd.) with a thickness of 0.6 mm was prepared. While peeling off the protective film from the photosensitive element, the photosensitive layer was laminated on the copper-clad laminate by using a press vacuum laminator (Product Name: “MVLP-500”, manufactured by Meiki Co., Ltd.), at a compression pressure of 0.4 MPa and a press heat plate temperature of 80° C. for a vacuuming time of 25 seconds and a laminating press time of 25 seconds, to obtain a laminate. Next, a negative mask including an opening pattern with a predetermined size (Opening Diameter Size: 30, 40, 50, 60, 70, 80, 90, 100, 110, 120, 150, and 200 μm) adhered to a carrier film of the laminate described above, and the photosensitive layer was exposed by using an ultraviolet ray exposure device (Product Name: “EXM-1201”, manufactured by Oak Inc.) at an exposed amount such that the number of steps of complete curing in a step tablet (manufactured by Showa Denko Materials Co., Ltd.) was 13 steps. After that, the carrier film was peeled off from the photosensitive layer, and spray-development was performed by using 1% by mass of an aqueous solution of sodium carbonate at a pressure of 1.765×10⁵ Pa for 60 seconds to dissolve and develop the unexposed portion. Next, the photosensitive layer after the development was exposed at an exposed amount of 2000 mJ/cm² by using an ultraviolet ray exposure device, and heated at 170° C. for 1 hour to produce a test piece including the cured film in which the opening pattern with a predetermined size was formed on the copper-clad laminate. The test piece described above was observed with an optical microscope, and evaluated on the basis of the following criteria.
A: The minimum diameter of a mask opening diameter was 30 μm or less.
B: The minimum diameter of a mask opening diameter was greater than 30 μm and 50 μm or less.
C: The minimum diameter of a mask opening diameter was greater than 50 μm.

(Resist Pattern Shape)

The test piece described above was cast in an embedding resin (using Product Name: “jER828”, manufactured by Mitsubishi Chemical Corporation, as an epoxy resin, and triethylene tetramine as a curing agent) and sufficiently cured, and then, polished with a polishing machine (Product Name: “Refine Polisher”, manufactured by Refine Tec Ltd.) to round off the sectional surface of the opening pattern of the cured film. The obtained sectional surface of the opening pattern was observed with a metallographic microscope, and evaluated on the basis of the following criteria.
A: Undercut and resist upper missing were not checked, and the linearity of the pattern outline was excellent.
B: Undercut or resist upper missing was checked, or the linearity of the pattern outline was poor.

(Thermal Shock Resistance)

A temperature cycle test was implemented for the test piece described above at −65° C. for 30 minutes and at 150° C. for 30 minutes as one cycle, and the test piece was observed visually and with an optical microscope at 1000 cycles and 2000 cycles, and evaluated on the basis of the following criteria.
A: The occurrence of a crack was not checked at 2000 cycles.
B: The occurrence of a crack was not checked at 1000 cycles, but the occurrence of a crack was checked at 2000 cycles.
C: The occurrence of a crack was checked at 1000 cycles.

TABLE 1

| | | Example | | | | | | | Comparative |
|---|---|---|---|---|---|---|---|---|---|
| | | 1 | 2 | 3 | 4 | 5 | 6 | 7 | Example 1 |
| (A) | A-1 | 18.3 | 18.3 | 18.3 | 18.3 | 18.3 | 18.3 | 18.3 | 18.3 |
| | A-2 | 18.3 | 18.3 | 18.3 | 18.3 | 18.3 | 18.3 | 18.3 | 18.3 |
| (B) | B-1 | 10.7 | 10.7 | 10.7 | 10.7 | 10.7 | 10.7 | 10.7 | 10.7 |
| | B-2 | 5.6 | 5.6 | 5.6 | 5.6 | 5.6 | 5.6 | 5.6 | 5.6 |
| (C) | C-1 | 0.9 | 0.9 | 0.9 | 0.9 | 0.9 | 0.9 | 0.9 | 0.9 |
| | C-2 | 0.1 | 0.1 | 0.1 | 0.1 | 0.1 | 0.1 | 0.1 | 0.1 |
| | C-3 | 0.1 | 0.1 | 0.1 | 0.1 | 0.1 | 0.1 | 0.1 | 0.1 |
| | C-4 | 0.1 | 0.1 | 0.1 | 0.1 | 0.1 | 0.1 | 0.1 | 0.1 |
| (D) | D-1 | 7.3 | — | — | — | — | — | — | — |
| | D-2 | — | 7.3 | — | — | — | — | — | — |
| | D-3 | — | — | 7.3 | — | — | — | — | — |
| | D-4 | — | — | — | 7.3 | — | — | — | — |
| | D-5 | — | — | — | — | 7.3 | — | — | — |
| | D-6 | — | — | — | — | — | 7.3 | — | — |
| | D-7 | — | — | — | — | — | — | 7.3 | — |
| | D-8 | — | — | — | — | — | — | — | 7.3 |
| (E) | E-1 | 17.5 | 17.5 | 17.5 | 17.5 | 17.5 | 17.5 | 17.5 | 17.5 |
| | E-2 | 13.3 | 13.3 | 13.3 | 13.3 | 13.3 | 13.3 | 13.3 | 13.3 |
| (F) | F-1 | 1.2 | 1.2 | 1.2 | 1.2 | 1.2 | 1.2 | 1.2 | 1.2 |
| (G) | G-1 | 0.8 | 0.8 | 0.8 | 0.8 | 0.8 | 0.8 | 0.8 | 0.8 |
| (H) | H-1 | 3.8 | 3.8 | 3.8 | 3.8 | 3.8 | 3.8 | 3.8 | 3.8 |
| | H-2 | 2 | 2 | 2 | 2 | 2 | 2 | 2 | 2 |

| | | | | | | | | |
|---|---|---|---|---|---|---|---|---|
| Resolution | B | B | A | A | A | A | B | C |
| Resist pattern shape | A | A | A | A | A | A | B | B |
| Thermal shock | B | B | A | A | A | B | B | C |
| resistance | | | | | | | | |

### REFERENCE SIGNS LIST

1: photosensitive element, 10: support film, 20: photosensitive layer, 30: protective film.

1. A photosensitive resin composition, comprising:
an acid-modified vinyl group-containing resin (A);
a thermosetting resin (B);
a photopolymerization initiator (C); and
a photopolymerizable compound (D),
wherein the photopolymerizable compound includes a photopolymerizable compound having a polyoxyalkylene chain and an ethylenically unsaturated group.

2. The photosensitive resin composition according to claim 1, wherein the number of oxyalkylene groups in the polyoxyalkylene chain is 2 to 50.

3. The photosensitive resin composition according to claim 1, wherein the number of oxyalkylene groups in the polyoxyalkylene chain is 10 to 35.

4. The photosensitive resin composition according to claim 1, wherein the photopolymerizable compound having a polyoxyalkylene chain and an ethylenically unsaturated group includes at least one type selected from the group consisting of an alkylene oxide-modified (meth)acrylate compound, an alkylene oxide-modified bisphenol A-type (meth)acrylate compound, an alkylene oxide-modified bisphenol F-type (meth)acrylate compound, an alkylene oxide-modified ditrimethylol propane (meth)acrylate compound, an alkylene oxide-modified dipentaerythritol (meth)acrylate compound, an alkylene oxide-modified pentaerythritol (meth)acrylate compound, an alkylene oxide-modified trimethylol propane (meth)acrylate compound, an alkylene oxide-modified diglycerin (meth)acrylate compound, and an alkylene oxide-modified glycerin (meth)acrylate compound.

5. The photosensitive resin composition according to claim 1, wherein the polyoxyalkylene chain includes at least one type selected from the group consisting of a polyoxyethylene chain, a polyoxypropylene chain, and a polyoxybutylene chain.

6. The photosensitive resin composition according to claim 1, wherein a content of the photopolymerizable compound is 1 to 15% by mass, on the basis of a total solid content in the photosensitive resin composition.

7. The photosensitive resin composition according to claim 1, further comprising an inorganic filler (E).

8. The photosensitive resin composition according to claim 1, further comprising an ion scavenger (G).

9. The photosensitive resin composition according to claim 1, further comprising an elastomer (H).

10. A photosensitive element, comprising a support film and a photosensitive layer formed on the support film,
wherein the photosensitive layer contains the photosensitive resin composition according to claim 1.

11. A printed wiring board, comprising a permanent resist containing a cured material of the photosensitive resin composition according to claim 1.

12. A method for producing a printed wiring board, comprising:
a step of forming a photosensitive layer on a substrate by using the photosensitive resin composition according to claim 1;
a step of forming a resist pattern by exposing and developing the photosensitive layer; and
a step of forming a permanent resist by curing the resist pattern.

13. A method for manufacturing a printed wiring board, comprising:
a step of forming a photosensitive layer on a substrate by using the photosensitive element according to claim 10;
a step of forming a resist pattern by exposing and developing the photosensitive layer; and
a step of forming a permanent resist by curing the resist pattern.
